(19) United States
(12) Patent Application Publication
(10) Pub. No.: US 2025/0072071 A1
(43) Pub. Date: Feb. 27, 2025

(54) TRANSISTOR STRUCTURE

(71) Applicant: United Microelectronics Corp., Hsinchu (TW)

(72) Inventors: Chih Wen Huang, Tainan City (TW); Shih An Huang, Tainan City (TW)

(73) Assignee: United Microelectronics Corp., Hsinchu (TW)

(21) Appl. No.: 18/467,739

(22) Filed: Sep. 15, 2023

(30) Foreign Application Priority Data
Aug. 23, 2023 (CN) 202311067294.5

(51) Int. Cl. H01L 29/10; H01L 29/06; H01L 29/78

(52) U.S. Cl. CPC H01L 29/1083; H01L 29/0653; H01L 29/1095; H01L 29/7816; H01L 29/7835

(57) ABSTRACT

A transistor structure includes a substrate, a first well region, a second well region, a gate structure, a drift region, a first doped region, a second doped region, and a first isolation structure. The first well region and the second well region are located in the substrate and adjacent to each other. The gate structure is located on the substrate. The drift region is located in the second well region on one side of the gate structure. The first doped region and the second doped region are located in the substrate on two sides of the gate structure. The first doped region is located in the first well region. The second doped region is located in the drift region. The first isolation structure is located in the substrate between the gate structure and the second doped region. The first well region has a first portion lower than a bottom surface of the drift region. The second well region has a second portion lower than the bottom surface of the drift region. A doping concentration of the first portion of the first well region is greater than a doping concentration of the second portion of the second well region.

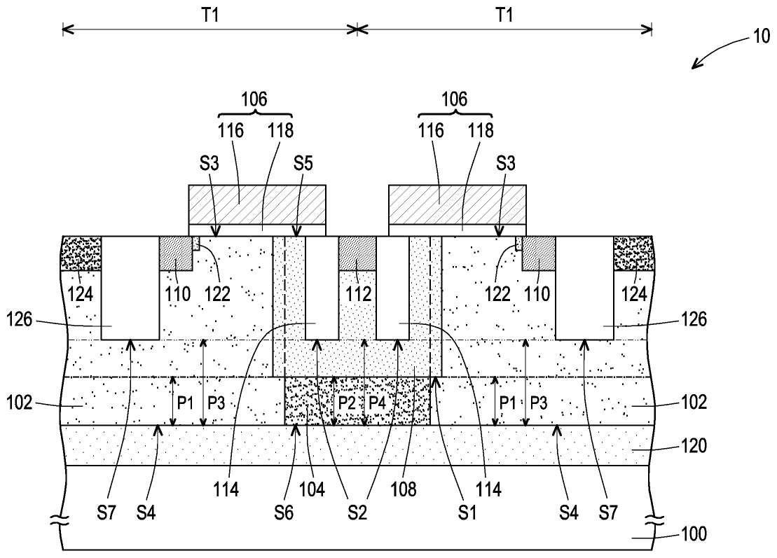

### CROSS-REFERENCE TO RELATED APPLICATION

This application claims the priority benefit of China application serial no. 202311067294.5, filed on Aug. 23, 2023. The entirety of the above-mentioned patent application is hereby incorporated by reference herein and made a part of this specification.

### BACKGROUND

### Technical Field

The disclosure relates to a semiconductor structure, and in particular, to a transistor structure.

### Description of Related Art

Currently, transistor structures are widely used in various electronic products. However, it is a goal of continuous efforts to further improve the electrical performance and reliability of the transistor structure.

### SUMMARY

The disclosure provides a transistor structure having more favorable electrical performance and more favorable reliability.

The disclosure provides a transistor structure, including a substrate, a first well region, a second well region, a gate structure, a drift region, a first doped region, a second doped region, and a first isolation structure. The first well region and the second well region are located in the substrate and adjacent to each other. The gate structure is located on the substrate. The drift region is located in the second well region on one side of the gate structure. The first doped region and the second doped region are located in the substrate on two sides of the gate structure. The first doped region is located in the first well region. The second doped region is located in the drift region. The first isolation structure is located in the substrate between the gate structure and the second doped region. The first well region has a first portion lower than a bottom surface of the drift region. The second well region has a second portion lower than the bottom surface of the drift region. A doping concentration of the first portion of the first well region is greater than a doping concentration of the second portion of the second well region.

According to an embodiment of the disclosure, in the above-mentioned transistor structure, the first well region can have a third portion lower than a bottom surface of the first isolation structure. The second well region can have a fourth portion lower than the bottom surface of the first isolation structure. A doping concentration of the third portion of the first well region can be greater than a doping concentration of the fourth portion of the second well region.

According to an embodiment of the disclosure, in the above-mentioned transistor structure, the first well region can have a top surface and a bottom surface opposite to each other. The top surface can be adjacent to the gate structure. The first well region can have a doping concentration increasing from the top surface to the bottom surface.

According to an embodiment of the disclosure, in the above-mentioned transistor structure, the second well region can have a top surface and a bottom surface opposite to each other. The top surface can be adjacent to the gate structure. The second well region can have a doping concentration decreasing from the top surface to the bottom surface.

According to an embodiment of the disclosure, in the above-mentioned transistor structure, the bottom surface of the drift region can be lower than the bottom surface of the first isolation structure. The drift region can surround the first isolation structure.

According to an embodiment of the disclosure, in the above-mentioned transistor structure, the drift region can be located in the first well region.

According to an embodiment of the disclosure, in the above-mentioned transistor structure, a part of the first well region can be located directly below the gate structure.

According to an embodiment of the disclosure, in the above-mentioned transistor structure, a part of the second well region can be located directly below the gate structure.

According to an embodiment of the disclosure, in the above-mentioned transistor structure, a part of the drift region can be located directly below the gate structure.

According to an embodiment of the disclosure, in the above-mentioned transistor structure, a part of the first isolation structure can be located directly below the gate structure.

According to an embodiment of the disclosure, in the above-mentioned transistor structure, the gate structure can include a gate and a gate dielectric layer. The gate is located on the substrate. The gate dielectric layer is located between the gate and the substrate.

According to an embodiment of the disclosure, in the above-mentioned transistor structure, the first well region and the second well region can have a first conductivity type. The drift region, the first doped region, and the second doped region can have a second conductivity type.

According to an embodiment of the disclosure, in the above-mentioned transistor structure, the substrate can have a first conductivity type.

According to an embodiment of the disclosure, the above-mentioned transistor structure can further include a third well region. The third well region is located in the substrate below the first well region and the second well region. The third well region can have a second conductivity type.

According to an embodiment of the disclosure, in the above-mentioned transistor structure, the first well region and the second well region can be connected to the third well region.

According to an embodiment of the disclosure, the above transistor structure can further include a lightly doped drain (LDD) region. The lightly doped drain region is located in the first well region between the first doped region and the gate structure. The lightly doped drain region can have a second conductivity type.

According to an embodiment of the disclosure, in the above-mentioned transistor structure, the lightly doped drain region can be located directly below the gate structure.

According to an embodiment of the disclosure, the above-mentioned transistor structure can further include a bulk region. The bulk region is located in the first well region. The first doped region can be located between the gate structure and the bulk region. The bulk region can have a first conductivity type.

According to an embodiment of the disclosure, the above-mentioned transistor structure can further include a second isolation structure. The second isolation structure is located in the substrate between the first doped region and the bulk region.

According to an embodiment of the disclosure, in the above-mentioned transistor structure, a bottom surface of the first well region can be lower than a bottom surface of the second isolation structure. The first well region can surround the second isolation structure.

Based on the above, in the transistor structure provided by the disclosure, the first well region has the first portion lower than the bottom surface of the drift region. The second well region has the second portion lower than the bottom surface of the drift region. The doping concentration of the first portion of the first well region is greater than the doping concentration of the second portion of the second well region. Therefore, the higher doping concentration of the first portion of the first well region can prevent the occurrence of punch through between the first doped region and the drift region, and the lower doping concentration of the second portion of the second well region can avoid excessive doping compensation effects at an overlap of the second portion and the drift region, so that the Kirk effect of the drift region and the damage caused by hot carriers generated by the local strong electric field can be reduced, and the electrical performance and reliability of the transistor structure can be improved.

In order to make the above-mentioned features and advantages of the disclosure clearer and easier to understand, the following embodiments are given and described below in details with accompanying drawings as follows.

### BRIEF DESCRIPTION OF THE DRAWINGS

FIGURE is a cross-sectional view of a transistor structure according to some embodiments of the disclosure.

### DESCRIPTION OF THE EMBODIMENTS

The following embodiments will be described in details with reference to the accompanying drawings, but the embodiments provided are not intended to limit the scope of the disclosure. In order to facilitate understanding, the same components will be described with reference to the same reference numerals in the following embodiments. In addition, the drawings are for description purposes only and may not be shown to original scale. In fact, for clarity of discussion, sizes of the various features can be arbitrarily enlarged or reduced.

FIGURE is a cross-sectional view of a transistor structure according to some embodiments of the disclosure.

Referring to FIGURE, a transistor structure T1 includes a substrate 100, a well region 102, a well region 104, a gate structure 106, a drift region 108, a doped region 110, a doped region 112, and an isolation structure 114. In some embodiments, the transistor structure T1 can be a laterally diffused metal oxide semiconductor (LDMOS) transistor structure. In some embodiments, the substrate 100 can be a semiconductor substrate, such as a silicon substrate. In some embodiments, the substrate 100 can have a first conductivity type (e.g., P-type).

Hereinafter, the first conductivity type and the second conductivity type can be one and the other of a P-type conductivity type and an N-type conductivity type, respectively. That is, the first conductivity type and the second conductivity type are different conductivity types. In the embodiment, the first conductivity type can be a P-type conductivity type, and the second conductivity type can be an N-type conductivity type, but the disclosure is not limited thereto. In other embodiments, the first conductivity type can be an N-type conductivity type, and the second conductivity type can be a P-type conductivity type.

The well region 102 and the well region 104 are located in the substrate 100 and adjacent to each other. In FIGURE, the boundary of a part of the well region 102 overlapping the drift region 108 is indicated by a bold dashed line, and the boundary of a part of the well region 104 overlapping the drift region 108 is indicated by a bold dashed line. In some embodiments, the well region 102 can be connected to or overlap the well region 104. In some embodiments, a part of the well region 102 can be located directly below the gate structure 106. In some embodiments, a part of the well region 104 can be located directly below the gate structure 106. The well region 102 and the well region 104 can have the same conductivity type. In some embodiments, the well region 102 and the well region 104 can have a first conductivity type (e.g., P-type).

The gate structure 106 is located on the substrate 100. In some embodiments, the gate structure 106 can include a gate 116 and a gate dielectric layer 118. The gate 116 is located on the substrate 100. In some embodiments, the gate 116 can be a doped polysilicon gate or a metal gate. The gate dielectric layer 118 is located between the gate 116 and the substrate 100. In some embodiments, the material of the gate dielectric layer 118 is, for example, silicon oxide.

The drift region 108 is located in the well region 104 on one side of the gate structure 106. In some embodiments, the drift region 108 can further be located in the well region 102. In some embodiments, a part of the drift region 108 can be located directly below the gate structure 106. In some embodiments, the drift region 108 can have a second conductivity type (e.g., N-type).

The doped region 110 and the doped region 112 are located in the substrate 100 on two sides of the gate structure 106. The doped region 110 is located in the well region 102. The doped region 112 is located in the drift region 108. In some embodiments, the doped region 110 can be used as a source region, and the doped region 112 can be used as a drain region. In some embodiments, the doped region 110 and the doped region 112 can have a second conductivity type (e.g., N-type).

The isolation structure 114 is located in the substrate 100 between the gate structure 106 and the doped region 112. In some embodiments, a bottom surface S1 of the drift region 108 can be lower than a bottom surface S2 of the isolation structure 114. In some embodiments, the drift region 108 can surround the isolation structure 114. In some embodiments, a part of the isolation structure 114 can be located directly below the gate structure 106. In some embodiments, the isolation structure 114 can be a shallow trench isolation (STI) structure. In some embodiments, the material of the isolation structure 114 is, for example, silicon oxide.

The well region 102 has a first portion P1 lower than the bottom surface S1 of the drift region 108. The well region 104 has a second portion P2 lower than the bottom surface S1 of the drift region 108. A doping concentration of the first portion P1 of the well region 102 is greater than a doping concentration of the second portion P2 of the well region 104. Therefore, the higher doping concentration of the first portion P1 of the well region 102 can prevent the occurrence of punch through between the doped region 110 and the drift region 108, and the lower doping concentration of the second portion P2 of the well region 104 can avoid excessive doping compensation effects at an overlap of the second portion P2 and the drift region 108, so that the Kirk effect of the drift region 108 and the damage caused by hot carriers generated by the local strong electric field can be reduced, and the electrical performance and reliability of the transistor structure T1 can be improved. In some embodiments, the well region 102 and the well region 104 can have a first conductivity type (e.g., P-type), and a doping concentration of the dopant of the first conductivity type (e.g., P-type dopant) in the first portion P1 of the well region 102 can be greater than a doping concentration of the dopant of the first conductivity type (e.g., P-type dopant) in the second portion P2 of the well region 104.

The well region 102 can have a third portion P3 lower than the bottom surface S2 of the isolation structure 114. The well region 104 can have a fourth portion P4 lower than the bottom surface S2 of the isolation structure 114. A doping concentration of the third portion P3 of the well region 102 can be greater than a doping concentration of the fourth portion P4 of the well region 104. The higher doping concentration of the third portion P3 can prevent the occurrence of punch through between the doped region 110 and the drift region 108, and the lower doping concentration of the fourth portion P4 can avoid excessive doping compensation effects at an overlap of the fourth portion P4 and the drift region 108, so that the Kirk effect of the drift region 108 and the damage caused by hot carriers generated by the local strong electric field can be reduced, and the electrical performance and reliability of the transistor structure T1 can be improved. In some embodiments, the well region 102 and the well region 104 can have the first conductivity type (e.g., P-type), and a doping concentration of the dopant of the first conductivity type (e.g., P-type dopant) in the third portion P3 of the well region 102 can be greater than a doping concentration of the dopant of the first conductivity type (e.g., P-type dopant) in the fourth portion P4 of the well region 104.

In some embodiments, the well region 102 can have a top surface S3 and a bottom surface S4 opposite to each other. The top surface S3 can be adjacent to the gate structure 106. In some embodiments, the well region 102 can have a doping concentration increasing from the top surface S3 to the bottom surface S4, thereby facilitating the optimization of the control capabilities of the threshold voltage (Vt) and the transistor gate. In some embodiments, the well region 104 can have a top surface S5 and a bottom surface S6 opposite to each other. The top surface S5 can be adjacent to the gate structure 106. The well region 104 can have a doping concentration decreasing from the top surface S5 to the bottom surface S6.

In some embodiments, the transistor structure T1 can further include a well region 120. The well region 120 is located in the substrate 100 below the well region 102 and the well region 104. In some embodiments, the well region 102 and the well region 104 can be connected to the well region 120. The well region 120 can have a second conductivity type (e.g., N type). In some embodiments, the well region 120 can be a deep well region (e.g., deep N-type well (DNW) region) having the second conductivity type.

In some embodiments, the transistor structure T1 can further include a lightly doped drain region 122. The lightly doped drain region 122 is located in the well region 102 between the doped region 110 and the gate structure 106. In some embodiments, the lightly doped drain region 122 can be located directly below the gate structure 106. In some embodiments, the lightly doped drain region 122 can have a second conductivity type (e.g., N-type).

In some embodiments, the transistor structure T1 can further include a bulk region 124. The bulk region 124 is located in the well region 102. The doped region 110 can be located between the gate structure 106 and the bulk region 124. In some embodiments, the bulk region 124 can have a first conductivity type (e.g., P-type).

In some embodiments, the transistor structure T1 can further include an isolation structure 126. The isolation structure 126 is located in the substrate 100 between the doped region 110 and the bulk region 124. In some embodiments, the bottom surface S4 of the well region 102 can be lower than a bottom surface S7 of the isolation structure 126. In some embodiments, the well region 102 can surround the isolation structure 126. In some embodiments, the isolation structure 126 can be a shallow trench isolation structure. In some embodiments, the material of the isolation structure 126 is, for example, silicon oxide.

In some embodiments, a semiconductor structure 10 can include a plurality of transistor structures T1. In some embodiments, two adjacent transistor structures T1 are disposed on two sides of the doped region 112 in a mirror-symmetric manner, and can share the substrate 100, the well region 104, the drift region 108, and the doped region 112. In some embodiments, the two adjacent transistor structures T1 can further share the well region 120.

Based on the above-mentioned embodiments, it can be known that in the transistor structure T1, the well region 102 has the first portion P1 lower than the bottom surface S1 of the drift region 108. The well region 104 has the second portion P2 lower than the bottom surface S1 of the drift region 108. The doping concentration of the first portion P1 of the well region 102 is greater than the doping concentration of the second portion P2 of the well region 104. Therefore, the higher doping concentration of the first portion P1 of the well region 102 can prevent the occurrence of punch through between the doped region 110 and the drift region 108, and the lower doping concentration of the second portion P2 of the well region 104 can avoid excessive doping compensation effects at an overlap of the second portion P2 and the drift region 108, so that the Kirk effect of the drift region 108 and the damage caused by hot carriers generated by the local strong electric field can be reduced, and the electrical performance and reliability of the transistor structure T1 can be improved.

To sum up, in the transistor structure of the above-mentioned embodiments, the first well region and the second well region are located in the substrate and adjacent to each other. The gate structure is located on the substrate. The drift region is located in the second well region on one side of the gate structure. The first doped region and the second doped region are located in the substrate on two sides of the gate structure. The first doped region is located in the first well region. The second doped region is located in the drift region. The first isolation structure is located in the substrate between the gate structure and the second doped region. The first well region has the first portion lower than the bottom surface of the drift region. The second well region has the second portion lower than the bottom surface of the drift region. The doping concentration of the first portion of the first well region greater than the doping concentration of the second portion of the second well region. Therefore, the higher doping concentration of the first portion of the first well region can prevent the occurrence of punch through between the first doped region and the drift region, and the lower doping concentration of the second portion of the second well region can avoid excessive doping compensation effects at an overlap of the second portion and the drift region, so that the Kirk effect of the drift region and the damage caused by hot carriers generated by the local strong electric field can be reduced, and the electrical performance and reliability of the transistor structure can be improved.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A transistor structure, comprising:
a substrate;
a first well region and a second well region, located in the substrate and adjacent to each other;
a gate structure, located on the substrate;
a drift region, located in the second well region on one side of the gate structure;
a first doped region and a second doped region, located in the substrate on two sides of the gate structure, wherein the first doped region is located in the first well region, and the second doped region is located in the drift region; and
a first isolation structure, located in the substrate between the gate structure and the second doped region, wherein
the first well region has a first portion lower than a bottom surface of the drift region,
the second well region has a second portion lower than the bottom surface of the drift region, and
a doping concentration of the first portion of the first well region is greater than a doping concentration of the second portion of the second well region.

2. The transistor structure according to claim 1, wherein
the first well region has a third portion lower than a bottom surface of the first isolation structure,
the second well region has a fourth portion lower than the bottom surface of the first isolation structure, and
a doping concentration of the third portion of the first well region is greater than a doping concentration of the fourth portion of the second well region.

3. The transistor structure according to claim 1, wherein
the first well region has a top surface and a bottom surface opposite to each other,
the top surface is adjacent to the gate structure, and
the first well region has a doping concentration increasing from the top surface to the bottom surface.

4. The transistor structure according to claim 1, wherein
the second well region has a top surface and a bottom surface opposite to each other,
the top surface is adjacent to the gate structure, and
the second well region has a doping concentration decreasing from the top surface to the bottom surface.

5. The transistor structure according to claim 1, wherein the bottom surface of the drift region is lower than a bottom surface of the first isolation structure, and the drift region surrounds the first isolation structure.

6. The transistor structure according to claim 1, wherein the drift region is further located in the first well region.

7. The transistor structure according to claim 1, wherein a part of the first well region is located directly below the gate structure.

8. The transistor structure according to claim 1, wherein a part of the second well region is located directly below the gate structure.

9. The transistor structure according to claim 1, wherein a part of the drift region is located directly below the gate structure.

10. The transistor structure according to claim 1, wherein a part of the first isolation structure is located directly below the gate structure.

11. The transistor structure according to claim 1, wherein the gate structure comprises:
a gate, located on the substrate; and
a gate dielectric layer, located between the gate and the substrate.

12. The transistor structure according to claim 1, wherein the first well region and the second well region have a first conductivity type, and the drift region, the first doped region, and the second doped region have a second conductivity type.

13. The transistor structure according to claim 12, wherein the substrate has the first conductivity type.

14. The transistor structure according to claim 12, further comprising:
a third well region, located in the substrate below the first well region and the second well region, wherein the third well region has the second conductivity type.

15. The transistor structure according to claim 14, wherein the first well region and the second well region are connected to the third well region.

16. The transistor structure according to claim 12, further comprising:
a lightly doped drain region, located in the first well region between the first doped region and the gate structure, wherein the lightly doped drain region has the second conductivity type.

17. The transistor structure according to claim 16, wherein the lightly doped drain region is located directly below the gate structure.

18. The transistor structure according to claim 12, further comprising:
a bulk region, located in the first well region, wherein the first doped region is between the gate structure and the bulk region, and the bulk region has the first conductivity type.

19. The transistor structure according to claim 18, further comprising:
a second isolation structure, located in the substrate between the first doped region and the bulk region.

20. The transistor structure according to claim 19, wherein a bottom surface of the first well region is lower than a bottom surface of the second isolation structure, and the first well region surrounds the second isolation structure.
